(19) United States
(12) Patent Application Publication
(10) Pub. No.: US 2020/0098959 A1
(43) Pub. Date: Mar. 26, 2020

(54) LIGHT-EMITTING DIODE LIGHTING STRUCTURE FOR IMPROVING BACK-ILLUMINATION EFFICIENCY

(71) Applicant: NATIONAL CENTRAL UNIVERSITY, Taoyuan City (TW)

(72) Inventors: Yi-Chun CHEN, Taoyuan City (TW); Ted Liang-tai LEE, Taoyuan City (TW); Ching-Cherng SUN, Taoyuan City (TW); Tsung-Xian LEE, Taoyuan City (TW)

(21) Appl. No.: 16/193,243

(22) Filed: Nov. 16, 2018

(30) Foreign Application Priority Data
Sep. 26, 2018 (TW) TW107133812

(51) Int. Cl. H01L 33/60; H01L 33/58; H01L 33/48

(52) U.S. Cl. CPC H01L 33/60; H01L 33/486; H01L 33/58

(57) ABSTRACT

A light-emitting diode lighting structure for improving back-illumination efficiency is revealed. The light-emitting diode lighting structure is disposed on a substrate and composed of a light emitting diode (LED) and a reflective panel. The LED provided with a packaging lens has a light emitting side and a backside. The reflective panel is arranged at the light emitting side of the LED and located adjacent to the packaging lens. A part of light emitted from the light emitting side is reflected to the substrate by the reflective panel. Thereby the illumination on the substrate at the backside can be increased. Moreover, continuous lighting is generated so that messages shown on signboards can be read more clearly and comfortably when a plurality of LEDs is disposed on and applied to the signboards.

### BACKGROUND OF THE INVENTION

### 1. Technical Field

The present invention relates to a light emitting diode (LED) lighting structure, especially to a light emitting diode (LED) assembly with higher backward illumination efficiency. More specifically, the present invention relates to a light emitting diode (LED) lighting structure with higher backward illumination efficiency, which is suitable for being applied to the signboards for showing messages/information.

### 2. Description of Related Art

Light emitting diode (LED) is used in a wide range of applications such as traffic signs, backlight units for liquid crystal displays (LCD), computers, indicators for home appliances and indicators for vehicles. In the LED available now, a lens is disposed on a light emitting side of the LED. However, the conventional lens has shortcomings of non-uniform lighting distribution and strong glare when the light is transmitted from the emitting surface to the reflective surface for forward and side illumination.

Refer to FIG. 1, a conventional road sign with a dot-matrix-designed light emitting diode (LED) usually uses through hole LEDs owing to advantages of low cost and popularity. While being applied to traffic signs, the through hole LED causes infinite contrast and glare. Moreover, the conventional area 510 illuminated by the LED 20 is quite small so that a combined message formed by point light sources shows a plurality of light spots spaced apart when a plurality of LEDs is arranged on the road sign for showing messages/information.

There is a significant difference between the above multi-spot message with spaced light spots and general messages formed by continuous lines. In fact, the point light sources spaced apart have the problems of discomfort, poor legibility, etc. Thus there is room for improvement, and there is a need to provide a light-emitting diode lighting structure with higher backward illumination efficiency for solving problems of conventional LED such as non-uniform light distribution, high glare level, discomfort in use, poor legibility, etc.

### SUMMARY OF THE INVENTION

Therefore it is a primary object of the present invention to provide a light-emitting diode lighting structure for improving back-illumination efficiency that improves legibility and comfort of information on signboards while being applied to the signboards.

In order to achieve the above object, a light-emitting diode lighting structure for improving back-illumination efficiency disposed on a substrate comprising: a LED that is provided with a packaging lens while a light emitting side and a backside opposite to the light emitting side are formed thereon according to emission direction thereof; and a reflective panel that is disposed on the light emitting side of the LED and located adjacent to the packaging lens; a part of light emitted from the light emitting side is reflected to the substrate on the backside by the reflective panel.

Implementation of the present invention at least produces the following advantageous effects:

1. The backward illumination efficiency of LED is improved effectively.
2. A better continuous lighting is provided when a plurality of LEDs is arranged and used.
3. Messages/information shown on signboards such as traffic signs can be perceived and recognized clearly and comfortably.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a schematic drawing showing conventional through hole LEDs applied to a traffic sign;

FIG. 2A is the first embodiment of a light-emitting diode lighting structure for improving back-illumination efficiency according to the present invention;

FIG. 2B is a sectional view of the first embodiment according to the present invention;

FIG. 2C is a sectional view of the first embodiment having a distance d according to the present invention;

FIG. 3A is the second embodiment of a light-emitting diode lighting structure for improving back-illumination efficiency according to the present invention;

FIG. 3B is a sectional view of the second embodiment according to the present invention;

FIG. 3C is a sectional view of the second embodiment having a distance d according to the present invention;

FIG. 4A is the third embodiment of a light-emitting diode lighting structure for improving back-illumination efficiency according to the present invention;

FIG. 4B is a sectional view of the third embodiment according to the present invention;

FIG. 4C is a sectional view of the third embodiment having a distance d according to the present invention;

FIG. 5A is the first embodiment added with a circular wall according to the present invention;

FIG. 5B is the first embodiment provided with a circular wall and a distance d according to the present invention;

FIG. 5C is the second embodiment provided with a circular wall according to the present invention;

FIG. 5D is the second embodiment provided with a circular wall and a distance d according to the present invention;

FIG. 5E is the third embodiment added with a circular wall according to the present invention;

FIG. 5F is the third embodiment provided with a circular wall and a distance d according to the present invention;

FIG. 6 is a schematic drawing showing the illuminated area before and after improvement of backward illumination according to the present invention;

FIG. 7 is a schematic drawing showing an embodiment used in a traffic sign according to the present invention.

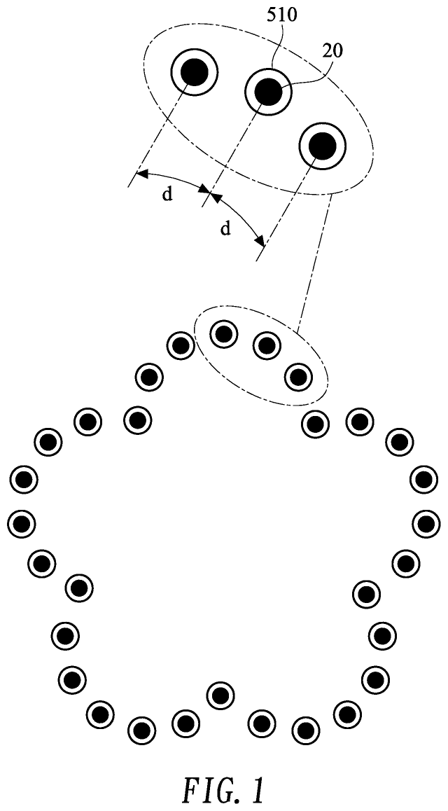

### DETAILED DESCRIPTION OF THE INVENTION

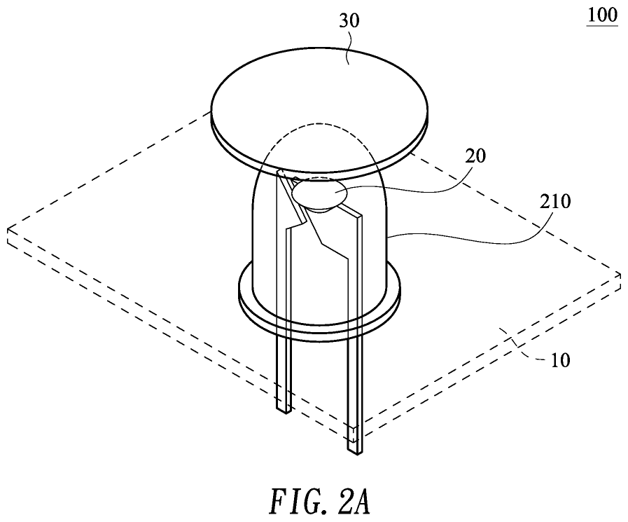

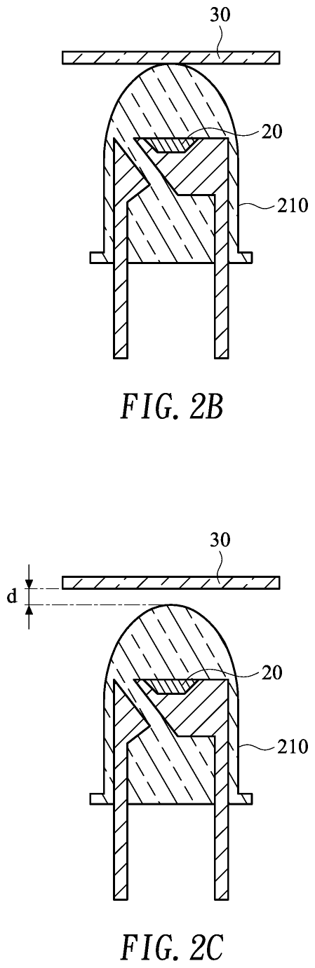

Refer to FIG. 2A-FIG. 4C, a light-emitting diode lighting structure for improving back-illumination efficiency 100 according to the present invention is disposed on a substrate 10 and composed of a light emitting diode (LED) 20 and a reflective panel 30.

The LED 20 is the light source of the light-emitting diode lighting structure for improving back-illumination efficiency 100. The LED 20 includes a packaging lens 210. According to the emission direction, a light emitting side toward the front side thereof and a backside opposite to the light emitting side are formed on the LED 20. The packaging lens 210 used for packaging the LED 20 can be dome lens or in other packaging forms.

The reflective panel 30 with a reflective surface is arranged at the light emitting side of the LED 20 and located adjacent to the packaging lens 210. The reflective panel 30 and the packaging lens 210 can be in direct contact with each other, or there is a certain distance (an interval) d between the reflective panel 30 and the packaging lens 210. Thereby a part of light emitted from the light emitting side of the LED 20 is reflected to the substrate 10 on the backside of the LED 20 by the reflective panel 30. Thus the illuminance on the substrate 10 is improved, or the illuminated area on the substrate 10 is increased.

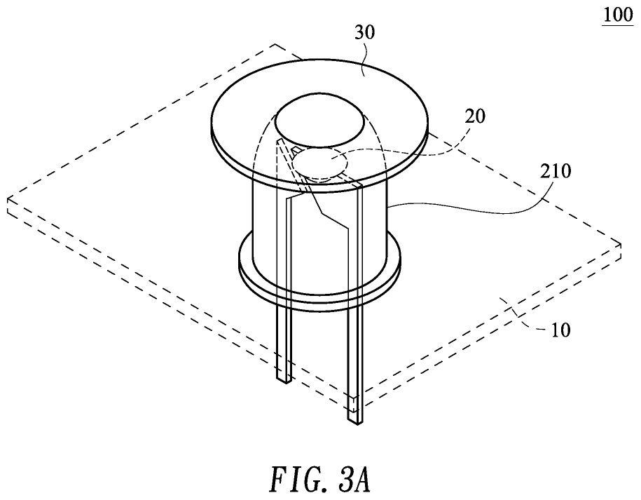

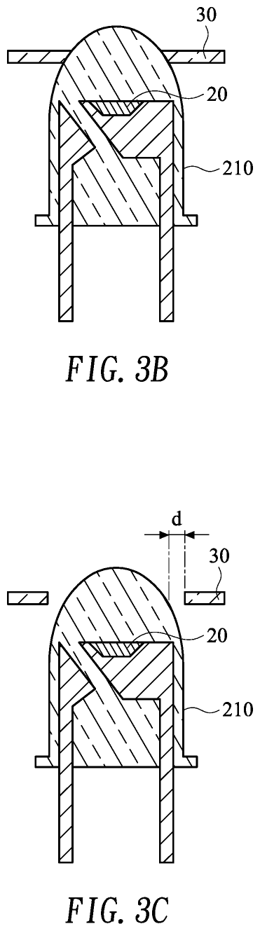

As shown in FIG. 3A and FIG. 3C, besides a flat board, the reflective panel 30 can be designed to have an opening that allows the packaging lens 210 on the light emitting side of the LED 20 to pass through.

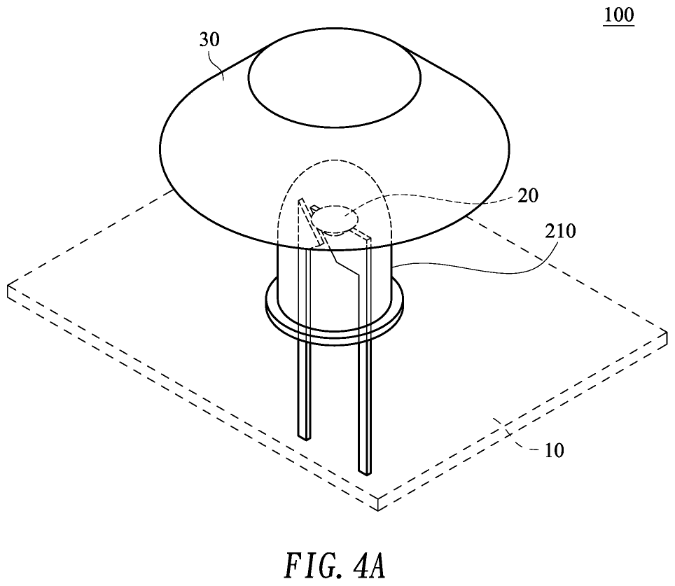

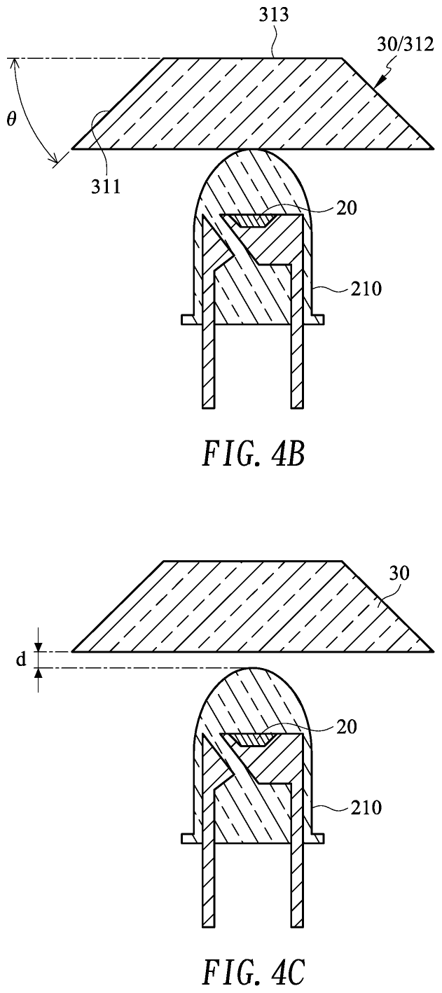

As shown in FIG. 4A-4C, the reflective panel 30 is a sector of an annulus that forms a lateral surface 311 of a right circular conical frustum 312. The angle θ between the lateral surface 311 and the top surface 313 of the right circular conical frustum 312 can be larger than 0 degree and less than 90 degrees, such as 45 degrees.

In order to balance illumination on the light emitting side and the backside while in use, the design of the reflective panel 30 can be modified for different applications. The reflectivity of the reflective panel 30 is designed to be ranging from 4% to 100% for balancing luminance at the light emitting side and luminance toward the substrate 10.

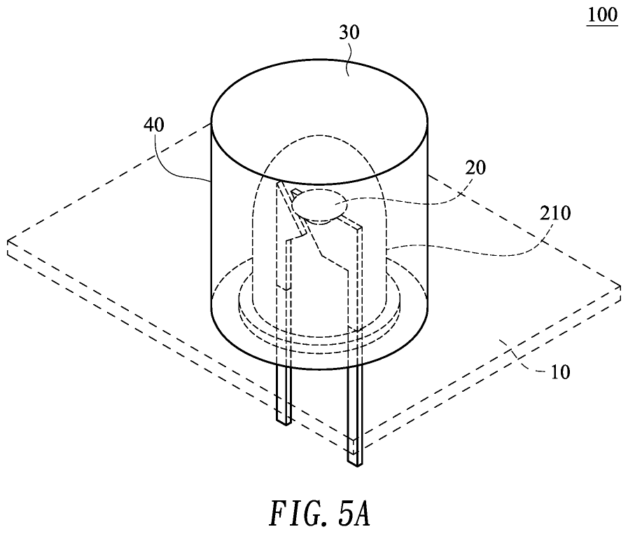

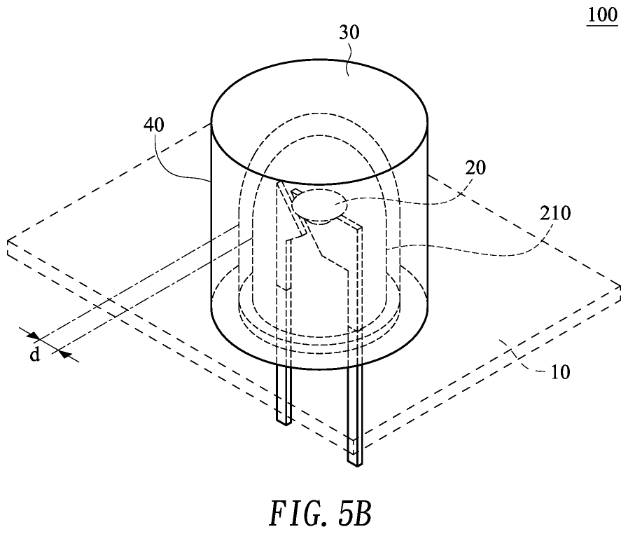

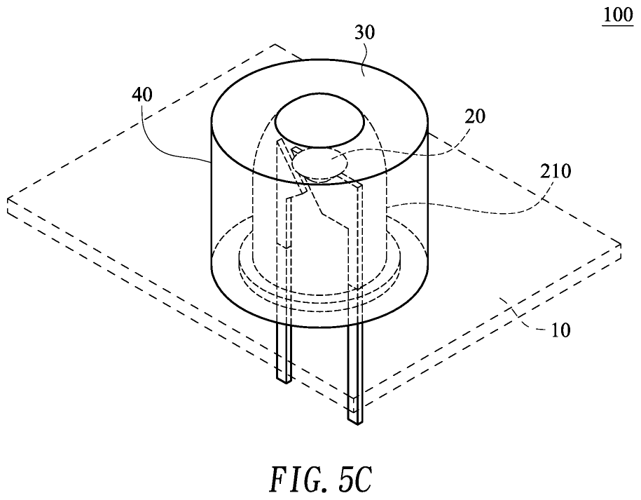

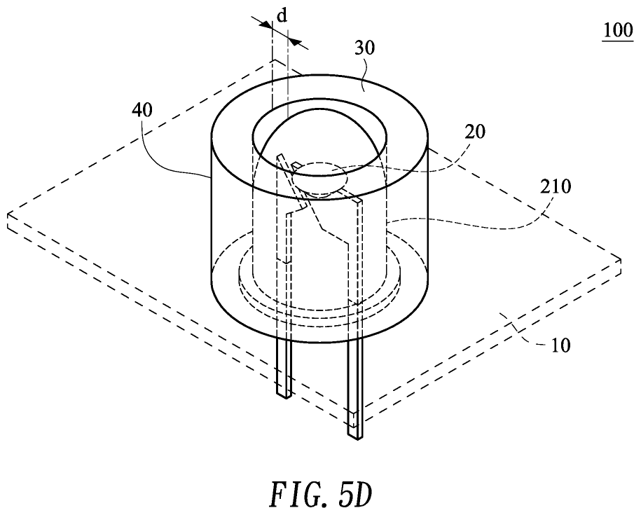

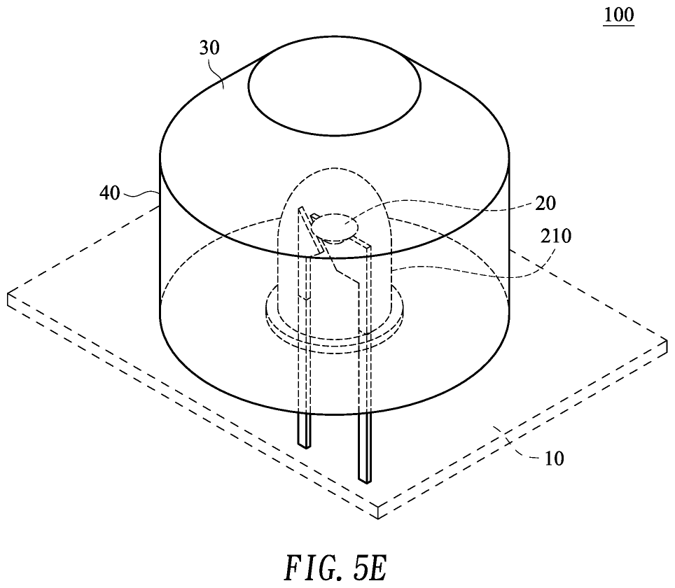

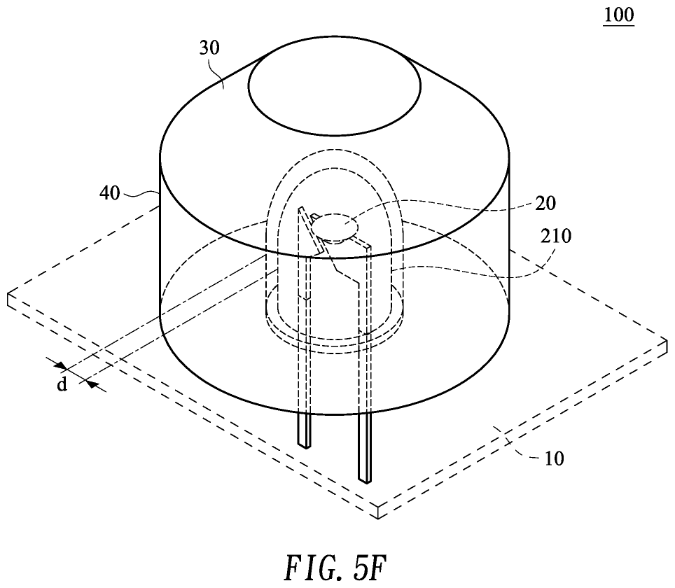

Refer to FIG. 5A-FIG. 5F, the reflective panel 30 further includes a circular wall 40 formed between the reflective panel 30 and the substrate 10. Similarly, the reflective panel 30 and the packaging lens 210 can be in direct contact or having a certain distance d therebetween. The circular wall 40 is not only used for supporting the whole reflective panel 30 but also used for mounting and protecting the LED 20. Moreover, the circular wall 40 can also be designed into a light converging element that converges the light reflected by the reflective panel 30.

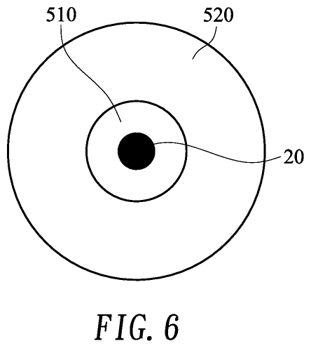

Refer to FIG. 6, owing to the implementation of the reflective panel 30 mentioned above, the illuminated area produced by the LED 20 onto the substrate 10 at the backside of the LED 20 is changed from the original conventional area 510 to an improved area 520. Both the illuminance and the size of the improved area 520 are improved and increased significantly.

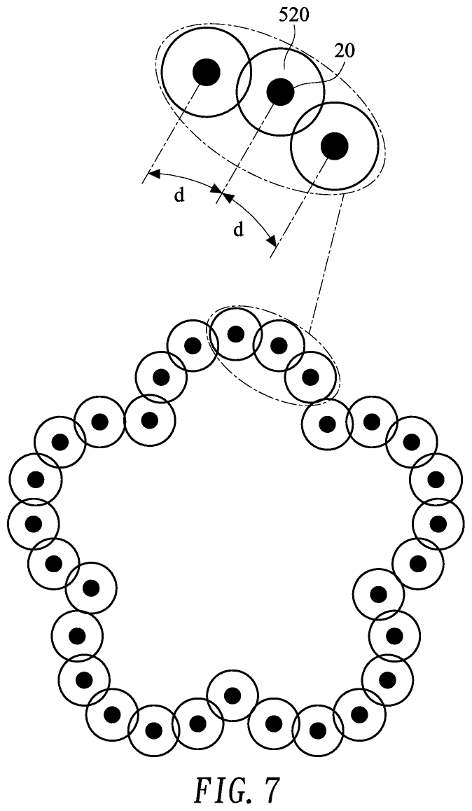

As shown in FIG. 7, while being applied to traffic sign boards, a dotted combined message presented by a plurality of conventional LEDs 20 on the signboard can be improved owing to the illuminated area produced by the LED 20 being enlarged to the improved area 520. The illuminated area of the two adjacent LEDs 20 intersects, and an overlapping area is formed therebetween so that the combined message becomes a continuous form. Thereby road users can read and recognize the traffic sign more clearly and comfortably. The legibility of the traffic sign is improved.

The above description is only the preferred embodiments of the present invention and is not intended to limit the present invention in any form. Although the invention has been disclosed as above in the preferred embodiments, they are not intended to limit the invention. A person skilled in the relevant art will recognize that equivalent embodiment modified and varied as equivalent changes disclosed above can be used without parting from the scope of the technical solution of the present invention. All the simple modification, equivalent changes and modifications of the above embodiments according to the material contents of the invention shall be within the scope of the technical solution of the present invention.

What is claimed is:

1. A light-emitting diode lighting structure for improving back-illumination efficiency disposed on a substrate comprising:
a LED that is provided with a packaging lens while a light emitting side and a backside opposite to the light emitting side are formed thereon according to the emission direction thereof; and
a reflective panel that is disposed on the light emitting side of the LED and located adjacent to the packaging lens; a part of light emitted from the light emitting side is reflected toward the substrate at the backside by the reflective panel.

2. The light-emitting diode lighting structure as claimed in claim 1, wherein a reflectivity of the reflective panel is ranging from 4% to 100%.

3. The light-emitting diode lighting structure as claimed in claim 1, wherein the reflective panel further includes a circular wall formed between the reflective panel and the substrate.

4. The light-emitting diode lighting structure as claimed in claim 1, wherein the reflective panel has an opening that allows the packaging lens on the light emitting side to pass through.

5. The light-emitting diode lighting structure as claimed in claim 4, wherein the reflective panel further includes a circular wall disposed between the reflective panel and the substrate.

6. The light-emitting diode lighting structure as claimed in claim 1, wherein the reflective panel is a sector of an annulus that forms a lateral surface of a right circular conical frustum.

7. The light-emitting diode lighting structure as claimed in claim 6, wherein an angle between the lateral surface and the top surface of the right circular conical frustum is larger than 0 degree and less than 90 degrees.

8. The light-emitting diode lighting structure as claimed in claim 7, wherein the angle is 45 degrees.

9. The light-emitting diode lighting structure as claimed in claim 6, wherein the reflective panel further includes a circular wall disposed between the sector of the annulus and the substrate.

10. The light-emitting diode lighting structure as claimed in claim 1, wherein the packaging lens is a dome lens.
